(19) United States
(12) Patent Application Publication
(10) Pub. No.: US 2026/0075339 A1
(43) Pub. Date: Mar. 12, 2026

(54) DIGITAL-TO-ANALOG CONVERSION CIRCUIT, OPERATING METHOD THEREOF, AND SOLID-STATE IMAGING DEVICE INCLUDING THE SAME

(71) Applicant: SAMSUNG ELECTRONICS CO., LTD., Suwon-si (KR)

(72) Inventor: Masahiro ICHIHASHI, Yokohama (JP)

(73) Assignee: SAMSUNG ELECTRONICS CO., LTD., Suwon-si (KR)

(21) Appl. No.: 19/324,703

(22) Filed: Sep. 10, 2025

(30) Foreign Application Priority Data
Sep. 10, 2024 (JP) 2024-156687
Jun. 19, 2025 (KR) 10-2025-0081221

(51) Int. Cl. H04N 25/78; H03M 1/06; H04N 25/616

(52) U.S. Cl. CPC H04N 25/78; H03M 1/0607; H04N 25/616

(57) ABSTRACT

There is provided an imaging device including a digital-analog conversion (DAC) circuit including a current source cell, a current-voltage conversion circuit that converts a signal variation of an output current of the current source cell into a first output voltage, a voltage divider circuit that divides the first output voltage of the current-voltage conversion circuit at a certain ratio and output a second output voltage, and an amplifier circuit that amplifies the second output voltage of the voltage divider circuit by driving a buffer, and generates a ramp signal based on the amplified second output voltage.

### CROSS-REFERENCE TO RELATED APPLICATION

This application is based on and claims priority under 35 U.S.C. § 119 to Japanese Patent Application No. 2024-156687, filed on Sep. 10, 2024, in the Japan Patent Office, and to Korean Patent Application No. 10-2025-0081221, filed on Jun. 19, 2025, in the Korea Patent Office, the disclosure of which is incorporated by reference herein in its entirety.

### BACKGROUND

### 1. Field

The disclosure relates to a digital-analog conversion (DAC) circuit, an operating method thereof, and a solid-state imaging device including the DAC circuit.

### 2. Description of Related Art

Recently, the miniaturization and high functionality of devices equipped with cameras such as mobile phones and digital cameras are rapidly progressing. For the miniaturization and high functionality of these devices, it is important to reduce the area and power consumption of image sensors.

An analog-to-digital converter that converts analog pixel signals output from pixels into digital signals is used in an image sensor. For example, as analog-to-digital converter of an image sensor, a single slope (SS) type analog-to-digital converter (hereinafter also referred to as “SS-ADC”) is known. Japanese Patent Publication No. 2020-120307 (Patent Document 1) describes an image sensor (an imaging device) for maintaining constant an initial voltage of an output voltage of a reference signal generator that supplies a ramp waveform to the SS-ADC. In the imaging device, the output voltage of the SS-ADC is obtained by applying an offset current and a current of the ramp wave (also called “a ramp current”) to a termination resistor according to a set analog gain. The ramp current is generated by a digital-to-analog converter of a reference signal generation portion.

However, according to the method described in Patent Document 1, settling of the ramp wave may take a long time due to a time constant determined by a terminal resistance and a parasitic resistance and a parasitic capacitance of a wiring. Furthermore, when the analog gain is dynamically changed, there may be cases where a DC level of the output voltage cannot be maintained constant. As a result, it may take a long time for the DC level of the output voltage to become stable.

### SUMMARY

One or more aspects of the disclosure provide a digital-analog conversion (DAC) circuit, an operating method thereof, and a solid-state imaging device including the conversion DAC circuit. According to one or more embodiments of the disclosure, the DAC circuit may reduce a settling time of a ramp wave while latching a DC level of an output voltage constant.

According to an aspect of the disclosure, there is provided an imaging device including: an analog-digital conversion (ADC) circuit configured to convert an analog signal from a pixel into a digital signal; and a digital-analog conversion (DAC) circuit including: a current source cell; a current-voltage conversion circuit configured to convert a signal variation of an output current of the current source cell into a first output voltage; a voltage divider circuit configured to divide the first output voltage of the current-voltage conversion circuit at a certain ratio and output a second output voltage; and an amplifier circuit configured to amplify the second output voltage of the voltage divider circuit by driving a buffer, generate a ramp signal based on the amplified second output voltage, and output the ramp signal to the ADC circuit.

According to another aspect of the disclosure, there is provided a digital-analog conversion (DAC) circuit including: a current source cell; a current-voltage conversion circuit configured to convert a signal variation of an output current of the current source cell into a first output voltage; a first voltage divider circuit configured to divide the first output voltage of the current-voltage conversion circuit at a first ratio and output a second output voltage; and a first amplifier circuit configured to amplify the second output voltage of the first voltage divider circuit, generate a first ramp signal based on the second output voltage amplified by the first amplifier circuit, and output the first ramp signal to an analog-digital conversion (ADC) circuit.

According to another aspect of the disclosure, there is provided an operating method of a digital-analog conversion (DAC) circuit for supplying a ramp signal to an analog-digital conversion (ADC) circuit, the operating method including: converting, by a current-voltage conversion circuit of the DAC circuit, a signal variation of an output current from a current source cell into a first voltage; dividing, by a voltage divider circuit of the DAC circuit, the first voltage to generate a second voltage; and amplifying, by an amplifier circuit of the DAC circuit, the second voltage through buffer driving to generate a ramp signal.

### BRIEF DESCRIPTION OF DRAWINGS

Embodiments will be more clearly understood from the following detailed description taken in conjunction with the accompanying drawings in which:

FIG. 1 is a block diagram of a solid-state imaging device according to an embodiment;

FIG. 2 is a timing diagram showing an operation of an analog-digital conversion circuit illustrated in FIG. 1;

FIG. 3 schematically illustrates a digital-to-analog conversion (DAC) circuit according to an embodiment;

FIG. 4A is a circuit diagram showing an example of a current source cell (ICELL) illustrated in FIG. 3;

FIG. 4B is a graph schematically showing a change over time of an output current I of the ICELL;

FIG. 5A is a circuit diagram showing an example of a current offset (IOFS) illustrated in FIG. 3;

FIG. 5B is a graph schematically showing a change over time of a current I₀ by a constant current source of the IOFS;

FIG. 5C is a graph schematically showing a change over time of a signal variation ΔI of an output current I of the IOFS;

FIG. 6A is a circuit diagram showing an example of a transimpedance amplifier (TIA) illustrated in FIG. 1;

FIG. 6B is a graph schematically showing a change over time of an input voltage Vᵥₛ input to an inverting input terminal of an operational amplifier of the TIA;

FIG. 6C is a graph schematically showing a change over time of an output voltage V_{TIA} of the TIA;

FIG. 7A is a circuit diagram showing an example of a voltage divider circuit (R2R) illustrated in FIG. 3;

FIG. 7B is a graph schematically showing a change over time of an output voltage V_{R2R} of the R2R;

FIG. 8A is a circuit diagram showing an example of capacitor buffer (CBUF) illustrated in FIG. 3;

FIG. 8B is a graph schematically showing a change over time of an output voltage Vout of the CBUF;

FIG. 9A is a waveform diagram showing an example of a ramp signal when an analog gain does not change between phases;

FIG. 9B is a waveform diagram showing an example of a ramp signal when the analog gain changes between the phases;

FIG. 10 is a circuit diagram showing an example of a DAC considering parasitic resistance, as a comparative example;

FIG. 11A is a circuit diagram showing an example of a DAC considering parasitic RC load on an output side, as a comparative example;

FIG. 11B is a graph showing an example of smoothing of a ramp signal by parasitic RC load;

FIG. 11C is a waveform diagram showing an example of a waveform of a ramp signal according to an analog gain in the DAC according to a comparative example;

FIG. 11D is a graph showing an example of settling according to an analog gain in the DAC according to a comparative example;

FIG. 11E is a graph showing an example of settling according to an analog gain in the DAC according to a comparative example;

FIG. 12 is a waveform diagram showing an example of a waveform of a ramp signal according to an analog gain in the DAC according to an embodiment;

FIG. 13A is a circuit diagram showing as an example of a double-sided auto-zero comparator;

FIG. 13B is a circuit diagram showing an example of a one-sided auto-zero comparator;

FIG. 14 is a circuit diagram showing an example of a comparator that includes a source follower-buffer;

FIG. 15 is a circuit diagram showing an example of a comparator that does not include a source follower-buffer;

FIG. 16A is a circuit diagram showing an example of a configuration for dual slope gain (DSG) driving by using the DAC according to a comparative example;

FIG. 16B is a waveform diagram showing an example of an operation by the configuration of FIG. 16A;

FIG. 17 is a waveform diagram showing an example of the waveform of a ramp signal having a plurality of slopes of different inclinations in one phase, according to an embodiment;

FIG. 18 schematically illustrates a DAC according to an embodiment;

FIG. 19 schematically illustrates a DAC according to an embodiment;

FIG. 20 is a waveform diagram showing an example of an inclination of a slope of a ramp signal before changing a resolution capability of a single slope (SS)-analog-to-digital converter (ADC);

FIG. 21 is a waveform diagram showing an example of an inclination of a slope of a ramp signal after changing a resolution capability of the SS-ADC; and

FIG. 22 is a flowchart showing an operating method of a DAC, according to an embodiment.

### DETAILED DESCRIPTION

Hereinafter, embodiments of the inventive concept are described in detail with reference to the accompanying drawings. In the following drawings, like reference numerals denote like elements, and the size of each element in the drawings may be expressed in a ratio different from the actual situation for clarity and convenience of description. Furthermore, as embodiments described below are examples, other modifications may be produced from the embodiments.

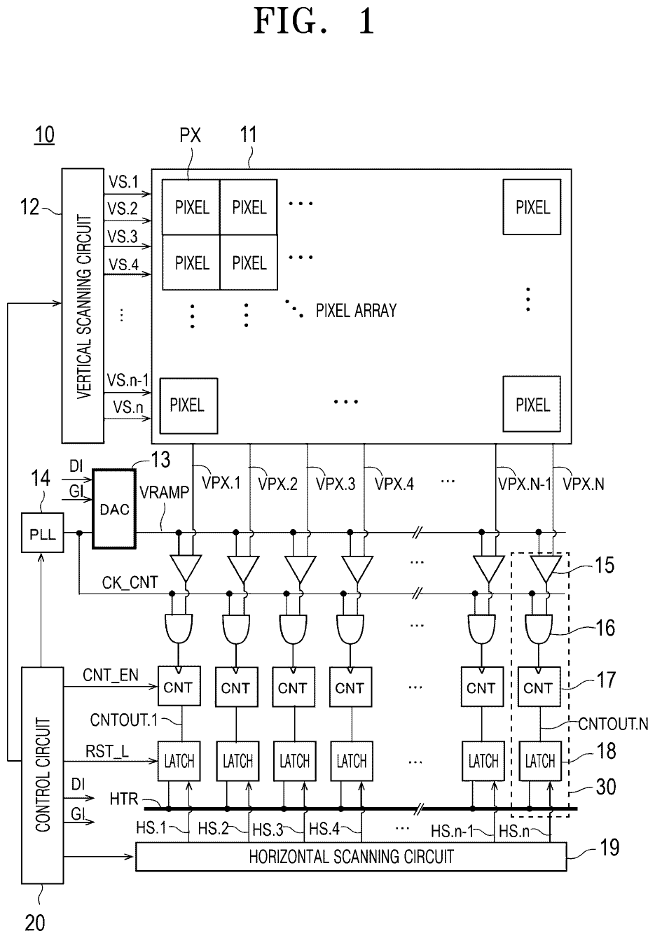

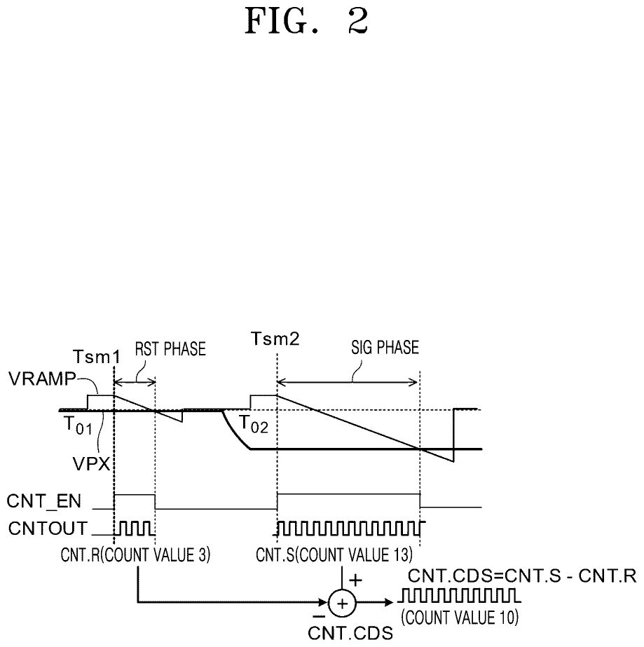

FIG. 1 is a block diagram of a solid-state imaging device 10 according to an embodiment. FIG. 2 is a timing diagram showing an operation of an analog-digital conversion (ADC) circuit 30 illustrated in FIG. 1.

The solid-state imaging device 10 may include a pixel array 11, a vertical scanning circuit 12, a digital-to-analog conversion (DAC) circuit 13, a phase locked loop (PLL) 14, a plurality of comparators 15, a plurality of AND elements 16, a plurality of counters (hereinafter, referred to as “CNT”) 17, a plurality of latches 18, a horizontal scanning circuit 19, and a control circuit 20. One comparator 15, one AND element 16, one CNT 17, and one latch 18 may constitute the analog-digital conversion (ADC) circuit 30. In some embodiments, the DAC circuit 13 may be referred to as digital-to-analog converter and the ADC circuit 30 may be referred to as the analog-digital converter. According to an embodiment, a plurality of ADCs 30 may be provided in the solid-state imaging device 10. For example, each of the plurality of ADCs 30 may correspond to a respective one of a plurality of columns of pixel circuits aligned in a vertical direction (column direction) in the pixel array 11.

The pixel array 11 includes a plurality of pixel circuits (hereinafter, simply referred to as “pixel (PX)”) arranged two-dimensionally in a row direction and the column direction (matrix arrangement). Each pixel PX may include a light receiving portion (photoelectric conversion element), a transfer transistor, a reset transistor, an amplification transistor, and a selection transistor, and perform photoelectric conversion on incident light to output an electrical signal according to the amount of incident light. The photoelectric conversion element may be, for example, a photodiode, a phototransistor, etc. The pixel array 11 may output analog pixel signals VPX.1 to VPX.N with respect to the pixels PX of the row selected by the vertical scanning circuit 12. The pixel signals VPX.1 to VPX.N are pixel signals of the pixels PX in the first column to the N-th column of the selected row. In the inventive concept, the pixels PX aligned in the row direction are referred to as a pixel row, and the pixels PX aligned in the column direction are referred to as a pixel column.

The vertical scanning circuit 12 may output a pulse signal to signal lines VS.1 to VS.n corresponding to a selected row to select one of a plurality of pixel rows included in the pixel array 11. The vertical scanning circuit 12 may include a vertical decoder and a vertical drive circuit. The vertical decoder may decode position information of the pixel PX designated by the control circuit 20 to designate a readout row in the vertical direction, that is, to select one of the plurality of pixel rows. The vertical drive circuit may supply a pulse signal to the pixel PX in the readout row defined by the vertical decoder to drive the pixel PX.

The DAC 13 may generate a voltage signal VRAMP (hereinafter, referred to as “ramp signal”) of a ramp waveform in which the voltage level gradually decreases as time passes and supply the ramp signal to the ADC 30 that converts an analog signal from the pixel PX into a digital signal. For example, the voltage signal VRAMP has a ramp waveform in which the voltage level monotonically decreases as time passes. The configuration and function of the DAC 13 are described below in detail.

The PLL 14 may generate a clock signal CK_CNT having a certain period T_{eye}. The PLL 14 may include a circuit for dividing an output signal by L, and generate a clock signal having a period of 1/L of the certain period T_{eye}.

The comparator 15 (or a comparison circuit) may compare the ramp signal VRAMP generated by the DAC 13 with a pixel signal VPX from the pixel array 11, and output a comparison result. The pixel signal VPX indicates a certain pixel signal among the pixel signals VPX.1 to VPX.N. In an example case in which the ramp signal VRAMP is greater than or equal to the pixel signal VPX in amplitude, the comparison result (e.g., a comparison result) may be a high level, and in an example case in which the ramp signal VRAMP is less than the pixel signal VPX in amplitude, the comparison result may be a low level.

The AND element 16 (e.g., an AND gate) may operate a logic operation (AND) of the comparison result of the comparator 15 and the clock signal CK_CNT from the PLL 14. The AND element 16 outputs a high level signal when the comparison result of the comparator 15 and the clock signal CK_CNT from the PLL 14 are both at a high level, and output a low level signal when at least one of the comparison result of the comparator 15 and the clock signal CK_CNT from the PLL 14 is at a low level. Accordingly, the AND element 16 may output the clock signal CK_CNT generated by the PLL 14 when the ramp signal VRAMP has an amplitude greater than or equal to that of the pixel signal VPX.

The CNT 17 may receive the output signal of the AND element 16 as a clock input, and count the received clock signal CK_CNT. Accordingly, as illustrated in FIG. 2, the CNT 17 may count the clock pulses of the clock signal CK_CNT from a measurement start time point Tsm (Tsm1 or Tsm2 in In FIG. 2) until the pixel signal VPX intersects the ramp signal VRAMP. The counting result (count value) of the CNT 17 becomes a digital value obtained by digitalizing the analog pixel signal VPX. For example, the control circuit 20 may output a count enable signal CNT_EN of an active level (high level) at the measurement start time point Tsm, and output the count enable signal CNT_EN of an inactive level (low level) when the pixel signal VPX interests the ramp signal VRAMP.

The CNT 17 may be, for example, an up counter or a down counter. In an example case in which the CNT 17 is an up counter, in a period in which the count enable signal CNT_EN is at an active level, the CNT 17 may count up from an initial value 0. In an example case in which the CNT 17 is a down counter, in a period in which the count enable signal CNT_EN is at an active level, the CNT 17 may count down from an initial value M. For example, the CNT 17 may output a count value CNTOUT.N.

The latch 18 may latch the count value CNTOUT.N of the CNT 17 to perform a correlated double sampling (CDS) process. The latch 18 may include a plurality of (e.g., two) latch circuits and a subtraction circuit. The ADC 30 may perform an AD conversion two times, for example, in an RST phase corresponding to the pixel signal VPX of a reset level and in an SIG phase corresponding to the pixel signal VPX of a signal level. The plurality of latches 18 may latch the count values of the CNT 17 in the RST phase and the SIG phase. The count value of the RST phase may indicate the signal value of a dark level, and the count value of the SIG phase may indicate the signal value of a white level.

The latch 18 may calculate a difference value CNT.CDS between a count value CNT.S corresponding to the pixel signal VPX of a signal level and a count value CNT.R corresponding to the pixel signal VPX of a reset level, so as to perform the CDS process. The CDS process may remove imbalance of the pixel signal VPX for each pixel PX. By subtracting the count value CNT.R of the CNT 17 in the RST phase from the count value CNT.S of the CNT 17 in the SIG phase, noise such as fixed pattern noise or reset noise of a pixel value including imbalance for each pixel PX may be removed. Accordingly, a pixel value corresponding to the signal level after noise removal may be calculated.

In an example illustrated in FIG. 2, the count value CNT.R of the RST phase may be 3, which may be the signal value of a dark level. The count value CNT.S of the SIG phase may be 13, which may be the signal value of a white level. The latch 18 may calculate and output a difference value 10 between a count value 13 corresponding to the pixel signal VPX of a signal level and a count value 3 corresponding to the pixel signal VPX of a reset level. In detail, the latch 18 may output the difference value 10 through a horizontal transmission line (HTR) in synchronism with selection signals HS.1 to HS.n supplied from the horizontal scanning circuit 19.

In an embodiment, the subtraction between the count value CNT.S of the SIG phase and the count value CNT.R of the RST phase may be performed by using an up/down counter. In this case, the CNT 17 may include an up/down counter, and the latch 18 may be omitted. The CNT 17 may count down in the RST phase and count up in the SIG phase. Accordingly, the subtraction between the count value CNT.S of the SIG phase and the count value CNT.R of the RST phase may be equivalently performed within the CNT 17, and the count value CNT.CDS (e.g., a difference value) according to the subtraction result may be latched in the CNT 17. Through the two times of count processing of counting down in the RST phase and counting up in the SIG phase, noise such as fixed pattern noise or reset noise of a pixel value including imbalance for each pixel PX may be removed. Accordingly, a pixel value corresponding to the signal level after noise removal may be calculated.

The horizontal scanning circuit 19 may output a selection signal HS of a pulse signal corresponding to the selected column, in order to select one of a plurality of pixel columns included in the pixel array 11. The selection signal HS indicates a certain selection signal among the selection signal HS.1 to HS.n. The horizontal scanning circuit 19 may have a horizontal decoder and a horizontal drive circuit. The horizontal decoder may decode position information of the pixel PX designated by the control circuit 20 to designate a readout column in the horizontal direction, that is, to select one of a plurality of pixel columns. The horizontal drive circuit may supply a pulse signal to the latch 18 in the readout column defined by the horizontal decoder to read out data latched in the latch 18.

The control circuit 20 may generate various timing signals and control signals, and perform driving control on the vertical scanning circuit 12, the DAC 13, the PLL 14, the horizontal scanning circuit 19, or the ADC 30 based on the generated signals. The control circuit 20 may generate a digital input signal DI and a gain input signal GI to generate a ramp current in the DAC 13.

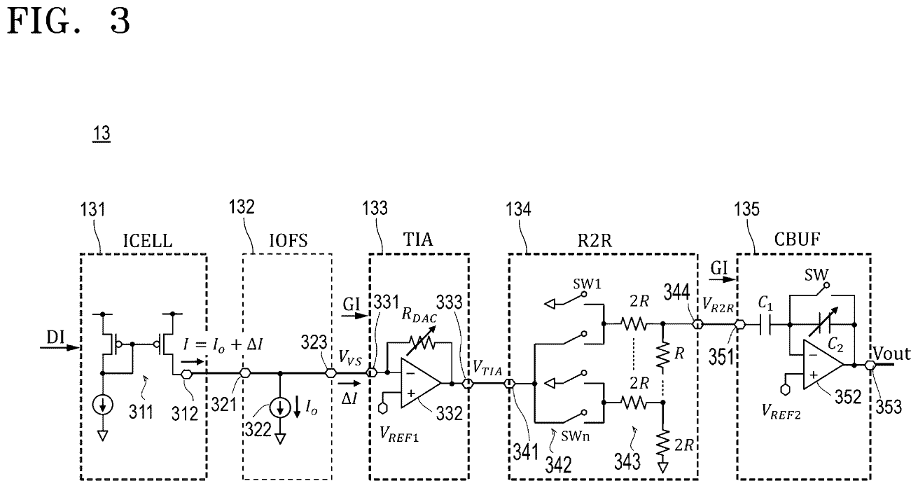

FIG. 3 schematically illustrates a DAC according to an embodiment. The DAC illustrated in FIG. 3 may be applied to the DAC 13 illustrated in FIG. 1. The DAC 13 may include five sub-blocks of an ICELL 131, an IOFS 132, a TIA 133, an R2R 134, and a CBUF 135. According to an embodiment, the ICELL 131, the IOFS 132, the TIA 133, the R2R 134, and the CBUF 135 may be connected to one another in the order shown in FIG. 3. However, the disclosure is not limited to the arrangement illustrated in FIG. 3.

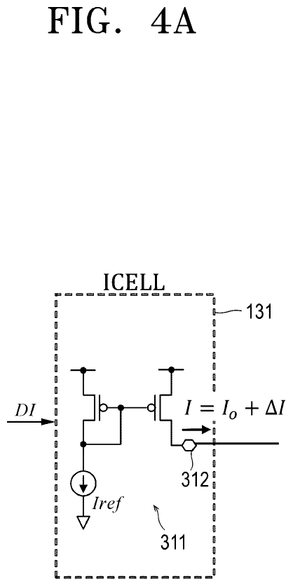

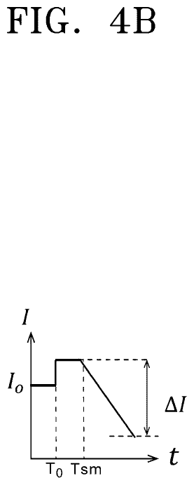

FIG. 4A is a circuit diagram showing an example of the ICELL 131 illustrated in FIG. 3. FIG. 4B is a graph schematically showing a change over time of an output current I of the ICELL 131. In FIG. 4B, the vertical axis represents the output current I of the ICELL 131, and the horizontal axis represents time. In addition, in “ICELL,” “I” denotes current, and “CELL” denotes a cell.

As illustrated in FIG. 4A, the ICELL 131 may function (or operate) as a current source cell portion, and generate and output an output current I (e.g., at output terminal 312) according to the digital input signal DI. The ICELL 131 may include a current mirror circuit 311. The current mirror circuit 311 may enable the output current I having an amplitude corresponding to a reference current I_{ref} at the input side. The reference current I_{ref} may be determined by, for example, a constant voltage from a constant voltage source and a resistance R_{S} set according to the digital input signal DI. For example, the output voltage of a band gap reference circuit may be used as the constant voltage. The output current I may satisfy, for example, I=α×I_{ref} (α≠0), and include an offset current I₀ and a signal variation ΔI. The offset current I₀ is a DC component of the output current I, and the signal variation ΔI is a signal variation of the output current I. The offset current I₀ may be set to zero.

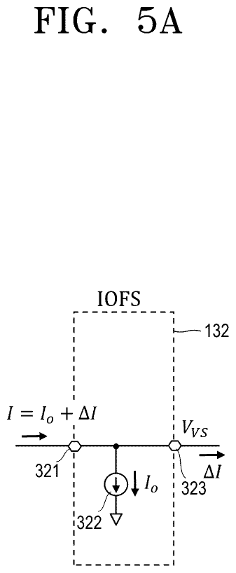

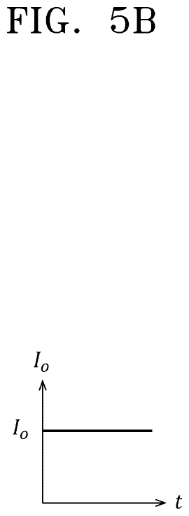

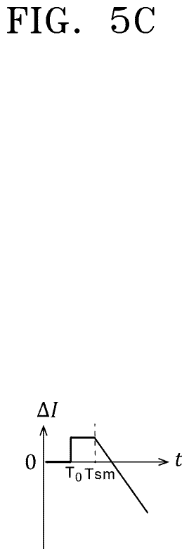

According to an embodiment, the ICELL 131 may include, for example, a plurality of unit current source cells connected in parallel and an input decoder. The input decoder may decode the digital input signal DI to generate a selection signal to select a desired unit current source cell among a plurality of unit current source cells. The digital input signal DI may be, for example, digital data (e.g., number) corresponding to each unit current source cell, and may be generated by the control circuit 20. In an example case in which a plurality of unit current source cells are all constant current sources that output a constant current of the same amplitude, the output current I of the ICELL 131 may be represented by a multiplication (IcxNs) of a current Ic output by one unit current source cell and the number Ns of the selected unit current source cells. In this case, as illustrated in FIG. 4B, the control circuit 20 may control the value of the digital input signal DI to the unit current source cells by the select maximum number (e.g., the number Nc of the total unit current source cells) at the measurement start time point Tsm, and reduce the number of the selected unit current source cells by one for each certain period Δt. Accordingly, the control circuit 20 may output the output current I having a step-like signal variation ΔI from the ICELL 131. In FIG. 4B, for convenience of illustration, the signal variation ΔI of the output current I is indicated by a smooth straight line (the same applies to FIGS. 5C, 6C, and 7B).

In an embodiment, the output current I of the ICELL 131 may be generated by previously setting a reference output current I_{S} and using the power of 2 of the reference output current I_{S}, that is, a combination of 2⁰×I_{S}, 2¹×I_{S}, 2²×I_{S}, . . . , 2^{k-1}×I_{S}. The control circuit 20 controls the ICELL 131 to output 2^{k-1}×I_{S} as the maximum output current I at the measurement start time point Tsm. In this case, the control circuit 20 controls the value of the digital input signal DI to reduce the output current I by I_{S} from 2^{k-1}×I_{S} for each certain period Δt so as to output the output current I having the step-like signal variation ΔI from the ICELL 131.

FIG. 5A is a circuit diagram showing an example of the IOFS 132 illustrated in FIG. 3. FIG. 5B is a graph schematically showing a change over time of the current I₀ by a constant current source of the IOFS 132. In FIG. 5B, the vertical axis represents the current I₀ by the constant current source, and the horizontal axis represents time. FIG. 5C is a graph schematically showing a change over time of the signal variation ΔI of the output current I of the IOFS 132. In FIG. 5C, the vertical axis represents the signal variation ΔI of the output current I of the IOFS 132, and the horizontal axis represents time. In addition, in “IOFS,” “I” denotes current, and “OFS” denotes offset.

The IOFS 132 receives the output current I (=I₀+ΔI) from the ICELL 131 and outputs the signal variation ΔI of the output current I. The IOFS 132 may include an input terminal 321, a constant current source 322, and an output terminal 323. The IOFS 132 may be configured to function (or operate) as an offset portion. The IOFS 132 may include the constant current source 322 that supplies a constant current equivalent to the offset current I₀ between the input terminal 321 (or the output terminal 323) and ground.

As illustrated in FIG. 5B, the constant current equivalent to the offset current I₀ is supplied from the constant current source 322. Accordingly, as illustrated in FIG. 5C, the signal variation ΔI obtained by removing an offset current (DC offset component) I₀ from the output current I (=I₀+ΔI) may be output from the IOFS 132. In an example case in which the offset current I₀ is not included in the output current I of the ICELL 131, the IOFS 132 may be omitted.

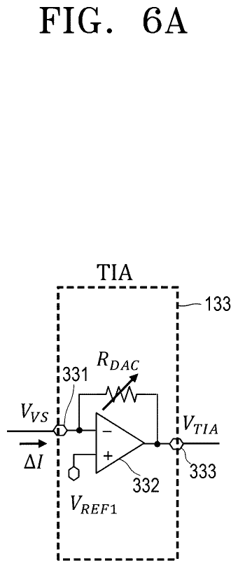

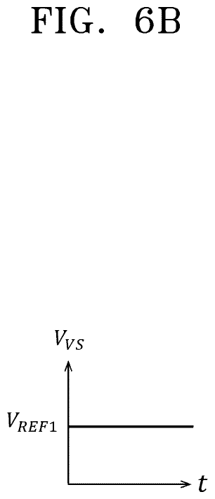

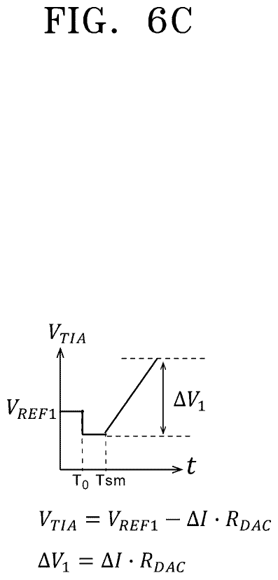

FIG. 6A is a circuit diagram showing an example of the TIA 133 illustrated in FIG. 3. FIG. 6B is a graph schematically showing a change over time of an input voltage Vᵥₛ input to an inverting input terminal of an operational amplifier of the TIA 133. In FIG. 6B, the vertical axis represents an input voltage Vᵥₛ, and the horizontal axis represents time. FIG. 6C is a graph schematically showing a change over time of an output voltage V_{TIA} of the TIA 133. In FIG. 6C, the vertical axis represents the output voltage V_{TIA}, and the horizontal axis represents time. In addition, “TIA” is an abbreviation for transimpedance amplifier, which refers in the inventive concept to a current-voltage conversion circuit that converts current into a voltage and amplifies the same.

As illustrated in FIG. 6A, the TIA 133 may function (or operate) as a current-voltage conversion circuit, and convert a current (signal variation) ΔI output from the IOFS 132 (or the ICELL 131) into the output voltage V_{TIA} and output the same. The TIA 133 may include an input terminal 331, an operational amplifier 332, a variable resistor R_{DAC}, and an output terminal 333. The operational amplifier (first operational amplifier) 332 and the variable resistor R_{DAC} may constitute a buffer drive circuit. The inverting input terminal of the operational amplifier 332 may be connected to the input terminal 331, and the output terminal of the operational amplifier 332 may be connected to the output terminal 333. A variable resistor R_{DAC} of negative feedback (feedback resistor) may be connected between the inverting input terminal and the output terminal of the operational amplifier 332.

As described below, analog gain (AG) of the DAC 13 may be adjusted by changing the resistance value of the variable resistor R_{DAC}. The analog gain AG is equivalent to the inclination of the output voltage V_{TIA} in FIG. 6C. In an example case in which the analog gain AG is adjusted to two times (e.g., AG=2) based on the analog gain AG being 1, the inclination of the output voltage V_{TIA} may become ½ of the inclination when the analog gain AG is 1, and in an example case in which the analog gain AG is adjusted to four times (e.g., AG=4), the inclination of the output voltage V_{TIA} may become ¼ of the inclination when the analog gain AG is 1. The buffer drive circuit may function (or operate) as a first analog gain setting portion.

The variable resistor R_{DAC} may include a plurality of resistors and a selection circuit for selecting a designated resistor among the plurality of resistors. The selection circuit may select one or more resistors from among a plurality of resistors according to the gain input signal GI. The selection circuit may include, for example, a decoder that decodes the gain input signal GI and generates a selection signal, and a conversion switch that switches the connection to the plurality of resistors by the generated selection signal. As the resistors connected in parallel are changed according to the selection signal generated by the decoder, the resistance value of the variable resistor R_{DAC} may be changed.

As illustrated in FIG. 6B, a first reference voltage V_{REF1} having a constant voltage level is input to a non-inverting input terminal (+terminal) of the operational amplifier 332 Also, as a current (e.g., the signal variation ΔI of the output current I from the ICELL 131) output from the IOFS 132 is input to the inverting input terminal (-terminal) of the operational amplifier 332, an input voltage Vᵥₛ may be generated. In this state, as a potential difference between the inverting input terminal of the operational amplifier 332 and the non-inverting input terminal becomes zero by virtual short, the input voltage Vᵥₛ may be the same as the first reference voltage V_{REF1}. The input voltage Vᵥₛ to the inverting input of the operational amplifier 332 may vary based on the first reference voltage V_{REF1} as operating point.

The output voltage V_{TIA} corresponding to a difference between the first reference voltage V_{REF1} input to the non-inverting input terminal and a voltage drop (ΔI×R_{DAC}) according to the input voltage Vᵥₛ input to the inverting input terminal may be output to the output terminal of the operational amplifier 332. Accordingly, as illustrated in FIG. 6C, the output voltage V_{TIA} of the operational amplifier 332 may be expressed by Equation 1 as follows.

$$[ Equation 1 ]$$

$${V}_{TIA} = {V}_{REF 1} - Δ I \cdot {R}_{DAC} = {V}_{REF 1} - Δ {V}_{1} \qquad ( l )$$

In addition, in the example described above, a case is described in which the operational amplifier 332 is used for a buffer driving circuit, but the inventive concept is not limited thereto, and an inverter circuit or a buffer circuit may be used for the buffer driving circuit. In an example case in which the inverter circuit or the buffer circuit is used, the DC level of the output voltage V_{TIA} may not be set to a certain level, but the DC level of the output voltage V_{TIA} may be latched constant.

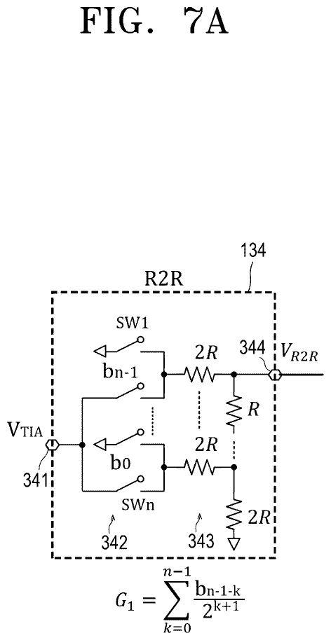

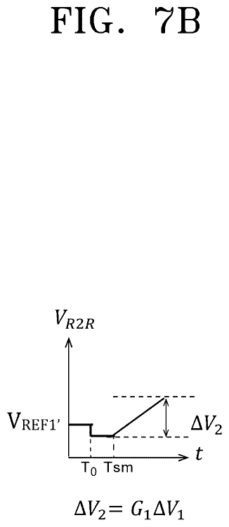

FIG. 7A is a circuit diagram showing an example of the R2R 134 illustrated in FIG. 3. FIG. 7B is a graph schematically showing a change over time of the output voltage V_{R2R} of the R2R 134. In FIG. 7B, the vertical axis represents the output voltage V_{R2R}, and the horizontal axis represents time.

The R2R 134 may receive the output voltage V_{TIA} of the TIA 133, and perform voltage division on the received output voltage V_{TIA} with powers of 2 to output the result as the output voltage V_{R2R}. The R2R 134 may function (or operate) as a voltage divider circuit. As illustrated in FIG. 7A, the R2R 134 may include an input terminal 341 connected to the output terminal 333 of the TIA 133, an input portion 342, a 1-resistor and 2-resistor (1R-2R) ladder circuit main body portion 343, and an output terminal 344.

As illustrated in FIG. 7A, the input portion 342 may include n switches (SW1 to SWn), and the n switches SW1 to SWn may each be switched to connect to the input terminal 341 of the R2R 134 or ground by a corresponding bit of n bits b₀ to bₙ₋₁ of the control signal. For example, the switch SW1 may be switched to connect to the input terminal 341 or ground by the bit bₙ₋₁ of the control signal, and the switch SWn may be switched to connect to the input terminal 341 or ground by the bit b₀ of the control signal. For example, the n switches SW1 to SWn may be configured to or controlled to switch independently or separately.

The 1R-2R ladder circuit main body portion 343 may include (n−1) first configurations including a resistor 2R having one end connected to a corresponding switch of the input portion 342 and a resistor R having a resistance value that is half the resistor 2R and one end connected to the other end of the resistor 2R. Furthermore, the 1R-2R ladder circuit main body portion 343 may include one second configuration including a resistor 2R having one end connected to a corresponding switch of the input portion 342 and another resistor 2R having one end connected to the other end of the resistor 2R. The other end of the resistor R is connected to a connection point of the resistor 2R and the resistor R of an adjacent first configuration. In the second configuration, the other end of the other resistor 2R is connected to ground. The output resistance of the 1R-2R ladder circuit main body portion 343, that is, synthesis resistance viewed from ground, is R. The 1R-2R ladder circuit main body portion 343 may function (or operate) as a second analog gain setting portion. As the 1R-2R ladder circuit main body portion 343 may be implemented by a combination of R and 2R, the 1R-2R ladder circuit main body portion 343 may be mounted in a relatively small area on a substrate.

A gain G₁ of the 1R-2R ladder circuit main body portion 343 may be expressed by Equation 2 below.

$$[ Equation 2 ]$$

$${G}_{1} = \frac{{V}_{R 2 R}}{{V}_{TIA}} = ( \frac{{b}_{n - 1}}{2} + \frac{{b}_{n - 2}}{4} + … + \frac{{b}_{1}}{{2}^{n - 1}} + \frac{{b}_{0}}{{2}^{n}} ) = {\sum }_{k = 0}^{n - 1} \frac{{b}_{n - 1 - k}}{{2}^{k + 1}} \qquad ( 2 )$$

Accordingly, as illustrated in FIG. 7B, a variable component ΔV₂ of the output voltage V_{R2R} may be expressed by Equation 3 below.

$$[ Equation 3 ]$$

$$Δ {V}_{2} = {G}_{1} Δ {V}_{1} = ( {\sum }_{k = 0}^{n - 1} \frac{{b}_{n - 1 - k}}{{2}^{( k + 1 )}} ) \cdot Δ I \cdot {R}_{DAC} \qquad ( 3 )$$

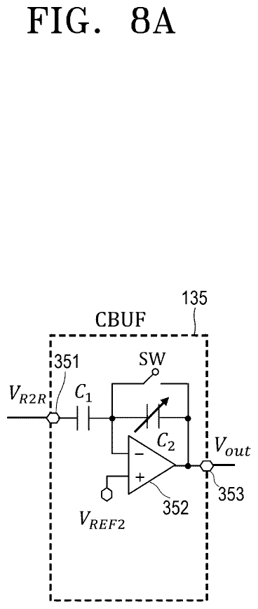

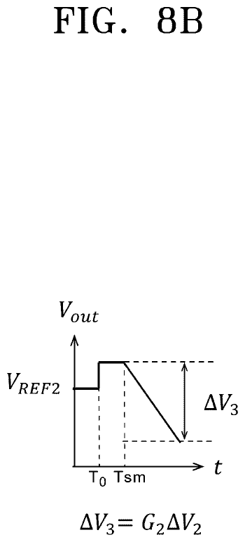

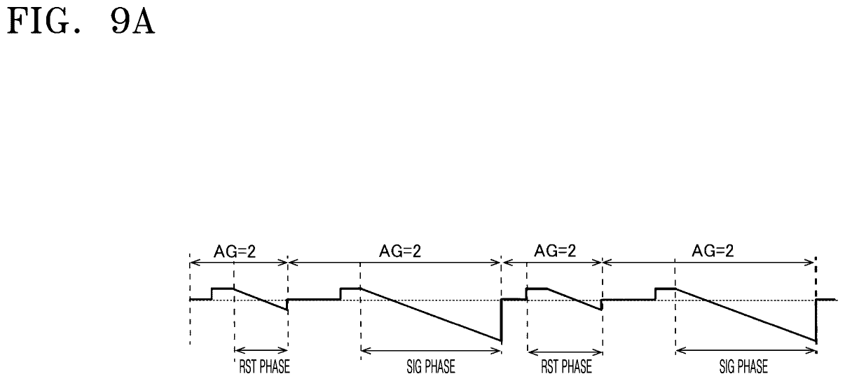

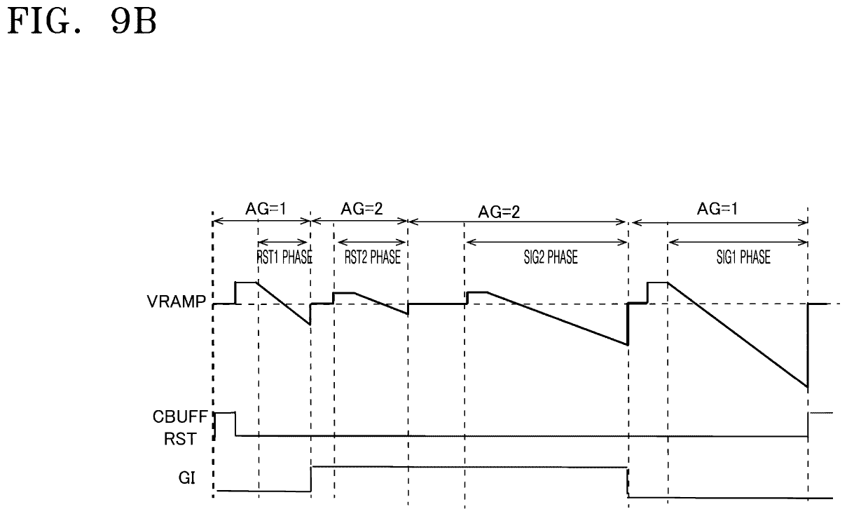

FIG. 8A is a circuit diagram showing an example of the CBUF 135 illustrated in FIG. 3. FIG. 8B is a graph schematically showing a change over time of an output voltage Vₒᵤₜ (e.g., a ramp signal) of the CBUF 135. In FIG. 8B, the vertical axis represents the output voltage Vₒᵤₜ, and the horizontal axis represents time. In addition, “CBUF” is an abbreviation for a capacitor buffer, which refers in the disclosure to a capacitor feedback buffer. FIG. 9A is a waveform diagram showing an example of a ramp signal when an analog gain does not change between phases, and FIG. 9B is a waveform diagram showing an example of a ramp signal when the analog gain changes between the phases.

As illustrated in FIG. 8A, the CBUF 135 may receive the output voltage V_{R2R} of the R2R 134, and buffer-drive and output a variable component ΔV₃ that is the remainder after removing a DC component from the output voltage V_{R2R}. The CBUF 135 may include an input terminal 351, an operational amplifier 352, an input capacitor C₁, a variable capacitor C₂, a switch SW, and an output terminal 353, and function (or operate) as an amplifier circuit. The operational amplifier (second operational amplifier) 352, the input capacitor C₁, and the variable capacitor C₂ may constitute a buffer driving circuit. The input capacitor C₁ is connected between the input terminal 351 of the CBUF 135 and the inverting input terminal of the operational amplifier 352, and the switch SW and the variable capacitor (feedback capacitor) C₂ of a negative feedback is connected between the inverting input terminal and the output terminal of the operational amplifier 352. The switch SW has a function to discharge the electric charges of the variable capacitor C₂ to reset the CBUF 135 (see FIG. 9B). Also, a constant second reference voltage V_{REF2} is input to the non-inverting input terminal of the operational amplifier 352. The output terminal of the operational amplifier 352 is connected, without change, to the output terminal 353 of the CBUF 135. The buffer driving circuit may function (or operate) as a third analog gain setting portion.

While the output voltage V_{R2R} (=V_{REF1}′+ΔV₂) from the R2R 134 is input to the input terminal 351, the variable component ΔV₂ in which a DC component V_{REF1}′ of the output voltage V_{R2R} is cut by the input capacitor C₁ may be input to the inverting input terminal of the operational amplifier 352. As a potential difference becomes zero due to virtual short between the inverting input terminal and the non-inverting input terminal of the operational amplifier 352, the DC voltage of the inverting input terminal may be the same as the second reference voltage V_{REF2}.

The variable capacitor C₂ may include a plurality of capacitors, and a selection circuit for selecting a designated capacitor of the plurality of capacitors. The selection circuit selects one or more capacitors according to a gain input signal GI from the plurality of capacitors. The selection circuit may include, for example, a decoder that decodes the gain input signal GI to generate a selection signal and a switch that switches connections of the plurality of capacitors according to the generated selection signal. As the capacitors that are connected in parallel according to the selection signal generated by the decoder are switched, the capacitance of the variable capacitor C₂ may be changed.

As illustrated in FIG. 8B, the CBUF 135 may amplify the variable component ΔV₂ by a gain G₂ times to output the amplified value to the output terminal 353. Accordingly, the variable component ΔV₃ obtained by amplifying, by the gain G₂ times, the variable component ΔV₂ input to the inverting input terminal is overlapped with the second reference voltage V_{REF2} input to the non-inverting input terminal, and then output as the output voltage Vₒᵤₜ to the output terminal 353 of the CBUF 135. The gain G₂ may be expressed by Equation 4 below.

$$[ Equation 4 ]$$

$${G}_{2} = \frac{{V}_{out}}{{V}_{R 2 R}} = \frac{{C}_{1}}{{C}_{2}} \qquad ( 4 )$$

Accordingly, the variable component ΔV₃ of the output voltage Vₒᵤₜ may be expressed by Equation 5 below.

$$[ Equation 5 ]$$

$$Δ {V}_{3} = {G}_{2} Δ {V}_{2} = \frac{{C}_{1}}{{C}_{2}} \cdot Δ {V}_{2} = Δ I \cdot {R}_{DAC} \cdot ( {\sum }_{k = 0}^{n - 1} \frac{{b}_{n - 1 - k}}{{2}^{k + 1}} ) \cdot \frac{{C}_{1}}{{C}_{2}} \qquad ( 5 )$$

In the ICELL 131, assuming that a reference current I_{ref} is determined by a ratio V_{BGR}/R_{S} of an output voltage V_{BGR} to the resistance R_{S} of the band gap reference circuit, and that an offset current I₀ is zero, Equation 5 may be expressed by Equation 6.

$$[ Equation 6 ]$$

$$Δ {V}_{3} = \frac{{V}_{BGR}}{{R}_{S}} \cdot {R}_{DAC} \cdot ( {\sum }_{k = 0}^{n - 1} \frac{{b}_{n - 1 - k}}{{2}^{k + 1}} ) \cdot \frac{{C}_{1}}{{C}_{2}} \qquad ( 6 )$$

In addition, although FIG. 8B illustrates an example in which the output voltage Vₒᵤₜ is a descending ramp wave, by inverting the current source polarity of FIG. 4A, the output voltage Vₒᵤₜ may become an ascending ramp wave.

Furthermore, although the above-mentioned example describes a case in which an operational amplifier is used as the buffer driving circuit, the disclosure is not limited thereto, and an inverter circuit or a buffer circuit may be used as the buffer driving circuit. In an example case in which an inverter circuit or a buffer circuit is in use, the DC level of the output voltage Vₒᵤₜ may not be set to a certain level, the DC level of the output voltage Vₒᵤₜ may be latched constant. Furthermore, as the output voltage Vₒᵤₜ is buffer-driven, the settling time of the ramp wave may be shortened.

Referring now to FIG. 3, in an embodiment, a method of inputting the signal variation ΔI of the output current I generated by the current source cell of the ICELL 131 to the operational amplifier 332 is employed. As described above, by the virtual short between the inverting input terminal and the non-inverting input terminal of the operational amplifier 332, the input electric potential of the TIA 133 becomes a constant electric potential corresponding to the first reference voltage V_{REF1}. Accordingly, a constant electric potential corresponding to the first reference voltage V_{REF1} is maintained at an operating point of the output of the ICELL 131.

In contrast, in a DAC according to a comparative example (e.g., a reference signal generation portion 15 in Japanese Patent Publication No. 2020-120307), as a current is applied to a termination resistor R_{T}, the voltages at the opposite ends of the termination resistor R_{T} may be greatly changed (swung).

That is, according to an embodiment of the disclosure, as the operating point of the output of the ICELL 131 in the DAC 13 maintains a constant electric potential, the operation range of the DAC 13 may be widened compared with the operation range of the DAC of the comparative example.

According to an embodiment of the disclosure, the analog gain of the DAC 13 may be changed by a method described below.

In an embodiment, the resistance value of the variable resistor R_{DAC} may be changed by inputting, to the gain input signal GI, a value corresponding to the resistance value of variable resistor R_{DAC} the TIA 133

In an embodiment, the gain G₁ may be changed by previously adjusting (setting) the resistance ratio (Equation 2) in the R2R 134. Accordingly, the analog gain may be previously adjusted before the operation of the DAC 13. For example, as illustrated in FIG. 9A, in an example case in which there is no need to change the analog gain in time, a constant analog gain may be obtained by changing the gain G₁ to previously adjust analog gain so as to obtain.

As such, the analog gain of the DAC 13 may not be changed dynamically by changing the gain G₁. This is because, as the DC component of V_{REF1} remains in the input signal (e.g., output voltage V_{TIA} of TIA 133) of the R2R 134, the remaining voltage is voltage-divided and regarded as a signal, and thus the DC level of the output voltage Vₒᵤₜ of the CBUF 135 may be changed.

In an embodiment, by inputting a value corresponding to the capacitance of the variable capacitor C₂ of the CBUF 135 to the gain input signal GI, the capacitance of the variable capacitor C₂ (e.g., a capacitor ratio C₁/C₂) may be changed. The analog gain of the DAC 13 may be dynamically adjusted (controlled) by changing the capacitance of the variable capacitor C₂.

As illustrated in FIG. 9B, as the resistance value of the variable resistor R_{DAC} and/or the capacitance of the variable capacitor C₂ (e.g., the capacitor ratio C₁/C₂) is changed according to the gain input signal GI, the analog gain of the DAC 13 may be dynamically controlled. In FIG. 9B, as the DAC 13 is dual slope gain (DSG)-driven so that the AD conversion may be performed in the phase order of RST1→RST2→SIG2→SIG1. In FIG. 9B, the analog gain AG is dynamically changed at the transition timing from the RST2 phase to the SIG2 phase by the gain input signal GI. The DSG driving is a technology to increase the dynamic range of a single slope (SS)-ADC by combining two different analog gains AGs with respect to the same pixel signal VPX. As a reset operation with respect to the CBUF 135 determines the DC level of a node between the input capacitor C₁ and the variable capacitor C₂, the reset operation may be performed only once in the RST phase for the first time.

In addition, in FIG. 9B, while the analog gain may be constant in each phase of the RST2 and the SIG2, that is, during outputting of the ramp signal, the analog gain may be dynamically changed during outputting of the ramp signal.

As such, according to an embodiment, the analog gain of the DAC 13 may be adjusted by using the methods described above. For example, the analog gain may be dynamically changed based on a first method of changing the resistance value of variable resistor R_{DAC} of the TIA 133,a second method of changing the capacitance of the variable capacitor C₂ of the CBUF 135, or a combination of the first method and the second method. The DAC 13 may change the analog gain while maintaining the DC level of the output voltage Vₒᵤₜ constant. As indicated in Equation 6, as all of the parameters of analog gain are determined by the resistance ratio and the capacitor ratio, the output voltage Vₒᵤₜ may have a very high precision.

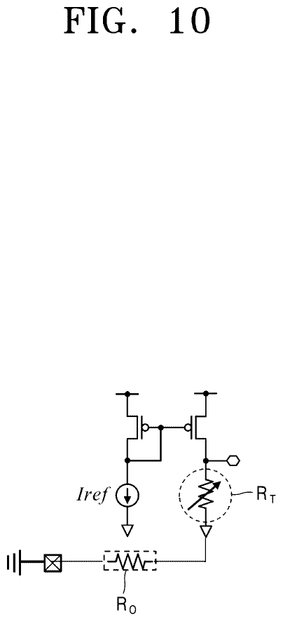

FIG. 10 is a circuit diagram showing an example of a DAC considering parasitic resistance, as a comparative example. The DAC according to the comparative example may include a current mirror circuit and the termination resistor R_{T} connected to the output side of the current mirror circuit, and an output current having an amplitude corresponding to the reference current I_{ref} of the input side flows in the termination resistor R_{T} by the current mirror circuit. The resistance value of the termination resistor R_{T} may decrease as the analog gain increases. For example, the resistance value of the termination resistor R_{T} when the analog gain AG is 1 is 128Ω, and when the analog gain AG is changed to 16, the resistance value of the termination resistor R_{T} becomes a very small value that is 128 Ω/16=8Ω. For example, when a parasitic resistor R₀ by an internal wiring is about 4Ω, there is an error that 4 Ω/8 Ω=50% so that analog gain control is difficult.

In contrast, as described with reference to FIG. 7A, the output resistance of the 1R-2R ladder circuit main body portion 343 in an embodiment is R, and cannot be less than R. Accordingly, by setting the value of the R of the 1R-2R ladder circuit main body portion 343 to a value that is sufficiently large than the parasitic resistance, the DAC 13 may be almost unaffected by the parasitic resistance such as internal wiring. Accordingly, even in an example case in which the analog gain control is multibit converted to set the analog gain AG to a large value, the effect by the parasitic resistance component on the output signal of the DAC 13 may be maintained small.

In the DAC according to the comparative example, by changing the resistance value of the termination resistor R_{T} that is variable, a desired analog gain may be set. The change of the termination resistor R_{T} is made, for example, by connecting a plurality of unit resistances RUs in parallel according to the resistance value of the termination resistor R_{T} corresponding to the desirable analog gain. However, for example, in a case in which the resistance value of the termination resistor R_{T} when the analog gain AG is 1 is 128Ω and a resolution is 10 bits, the resistance value of the unit resistor RU is 128 Ω/210=0.125Ω, which is a very small value. As it is difficult to implement the unit resistor RU of such a small resistance value by one resistor, arranging a plurality of resistors of several kΩ in parallel may be considered for implementation. However, in a method of arranging a plurality of resistors of several kΩ in parallel, the number of resistors in unit is huge, and thus the area of a substrate occupied by the resistors may increase very large.

In contrast, in the DAC 13 according to an embodiment, the analog gain may be adjusted by changing at least one of a resistance value of the variable resistor R_{DAC} of the TIA 133, the resistance ratio of the 1R-2R ladder circuit main body portion 343 of the R2R 134, and the capacitor ratio C₁/C₂ (e.g., the capacitance of the variable capacitor C₂) of the CBUF 135. Accordingly, there is no need to arrange the termination resistor R_{T} that occupies a large area on the substrate.

As such, in the DAC 13 according to an embodiment, compared with the DAC according to the comparative example, as the termination resistor R_{T} that occupies a large area is not used, the resistance area on the substrate may be reduced.

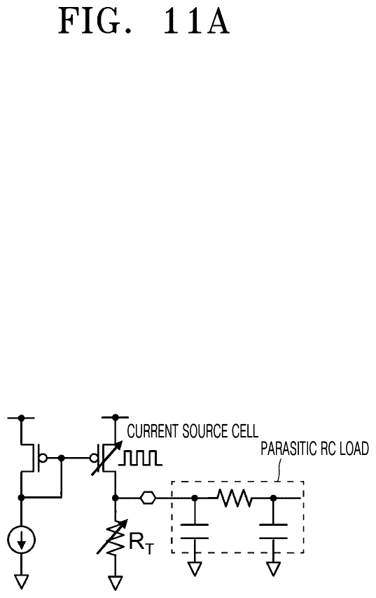

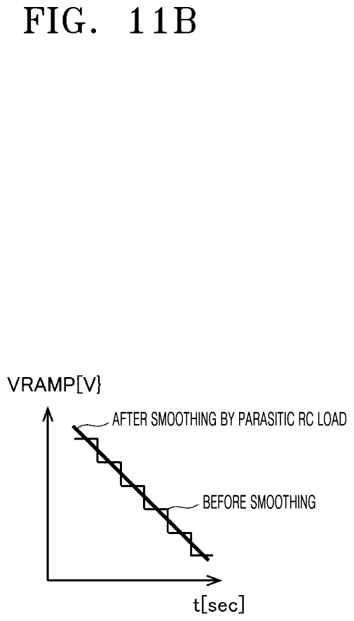

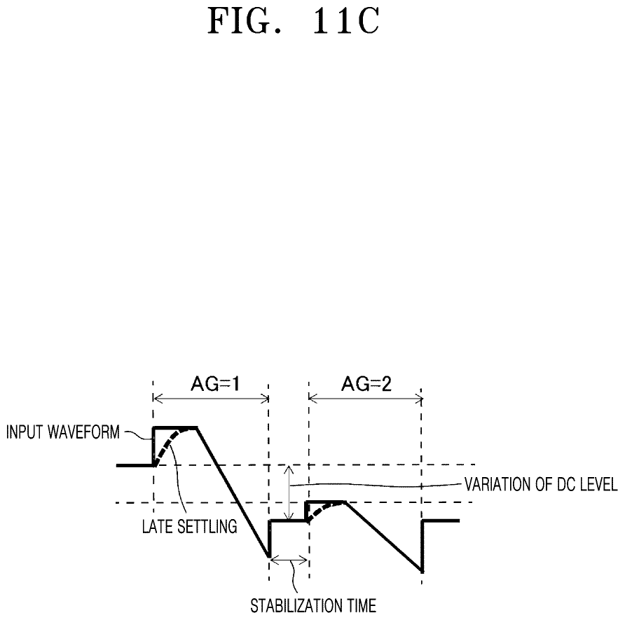

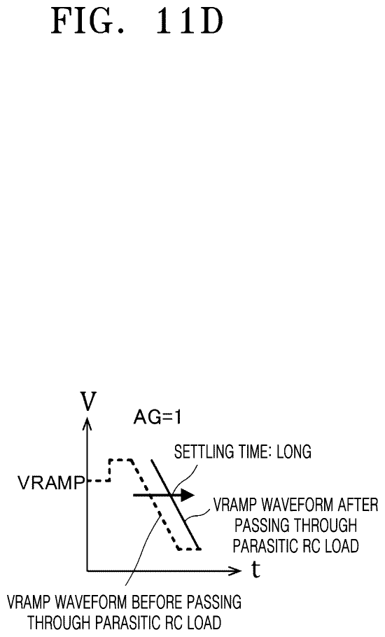

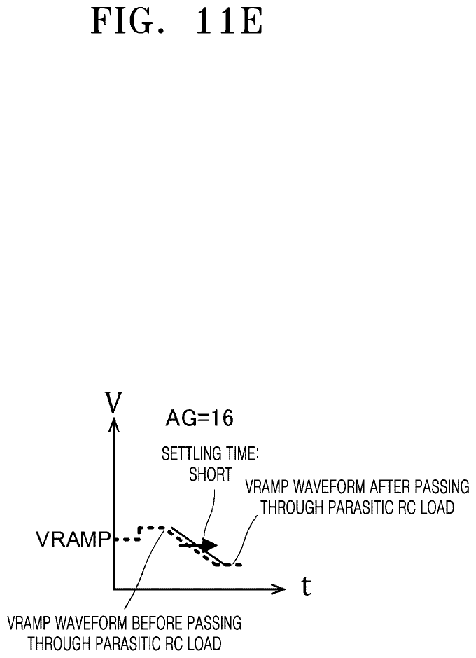

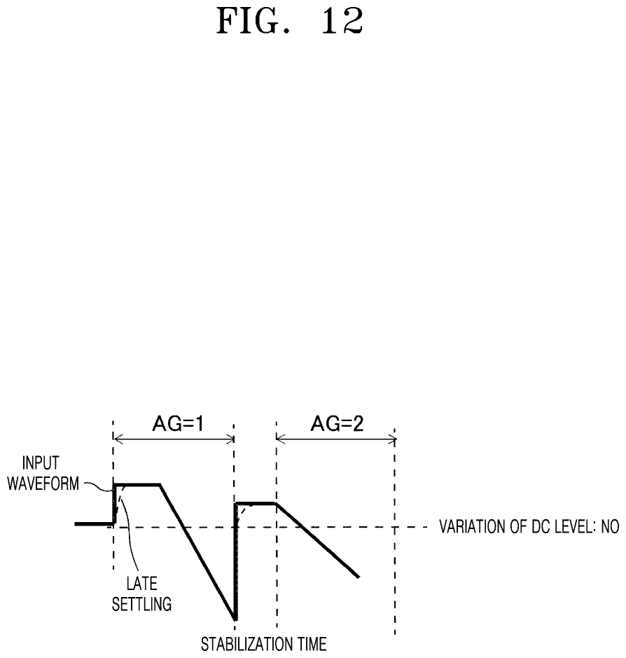

FIG. 11A is a circuit diagram showing an example of a DAC considering parasitic RC load on an output side, as a comparative example. FIG. 11B is a graph showing an example of smoothing of a ramp signal by a parasitic RC load. FIG. 11C is a waveform diagram showing an example of the waveform of a ramp signal according to an analog gain in the DAC according to a comparative example. FIGS. 11D and 11E are graphs showing an example of settling according to an analog gain in the DAC according to a comparative example. FIG. 12 is a waveform diagram showing an example of the waveform of a ramp signal according to an analog gain in the DAC 13 according to an embodiment.

As illustrated in FIG. 11A, in the DAC according to the comparative example, a parasitic RC load exists on the output side. The parasitic RC load is, for example, a load of a comparator connected to a rear end of the DAC according to the comparative example, and may be represented by an RC circuit connected to the termination resistor R_{T} in parallel. The current source cell may include, for example, a plurality of unit current source cells that generate constant currents of different amplitudes. As illustrated in FIG. 11B, the current source cell generates a step current as the respective unit current source cells are sequentially switched by high-speed clock signals, and generates a step voltage by applying the step current to the termination resistor R_{T}. The step voltage is smoothed by the parasitic RC load so as to generate a ramp signal.

In the DAC according to the comparative example, a considerable time is taken for the settling of a ramp signal due to the termination resistor R_{T} and the parasitic RC load. The delay in the settling time undesirably causes a delay in the waveform generation of a ramp signal of the DAC and the conversion operation of the SS-ADC, and further a delay in framerate in image generation.

As illustrated in FIG. 11C, when the analog gain AG is adjusted from 1 (one time) to 2 (two times), the termination resistor R_{T} is changed to half the value, and thus as the DC level is halved, the settling time of a ramp signal changes. The settling time of a ramp signal is dependent on a time constant determined by the termination resistor R_{T} and the parasitic RC load and becomes shorter when the analog gain AG is 2 than when the analog gain AG is 1. As illustrated in FIGS. 11D and 11E, compared with a case where the analog gain AG is 1, when the analog gain AG is 16, the settling time of the ramp signal VRAMP is further shortened (a difference in the length of arrows in FIGS. 11D and 11E indicates a difference in the length of the settling time). As such, in the DAC according to the comparative example, when the analog gain AG=1, the settling of the ramp signal VRAMP is relatively slow (the settling time increases), and as the analog gain AG increases, the settling of the ramp signal VRAMP is relatively fast (the settling time decreases). However, the speed (settling time) of the settling of the ramp signal VRAMP varies depending on the analog gain AG.

In contrast, as illustrated in FIG. 12, in an embodiment of the disclosure, the output of the DAC 13 is always driven with low-output impedance by the operational amplifier 352 of the CBUF 135. Accordingly, the ramp signal VRAMP is settled at high speed without being dependent on the analog gain AG. In other words, compared with the DAC according to the comparative example, the settling time of the ramp signal VRAMP is short.

In the DAC according to the comparative example, as the current generated by the current source cell is applied to the termination resistor R_{T}, the value of the termination resistor R_{T} changes, and when the analog gain AG changes, the DC level of the output voltage simultaneously changes. When the DC level of the output voltage of the DAC changes according to the change of the analog gain AG, it is necessary to design a circuit (e.g., comparator) connected to the rear end of the DAC to accommodate the change of the DC level of the DAC, which makes the design more complex. In an example case in which the rear-end circuit does not correspond to the change of the DC level of the DAC, an operating range of the rear-end circuit of the DAC may narrow. In this case, it may be difficult to perform voltage reduction at the rear-end circuit.

Also, as illustrated in FIG. 11C, in the DAC according to the comparative example, it is necessary to secure a stabilization time for the stabilization of the DC level in accordance with a variation in the DC level of the output voltage. As a result, it is difficult to perform a high-speed operation of ADC for converting an analog signal from the pixel PX into a digital signal.

In contrast, according to the embodiment as described above, the DC level of the output voltage Vₒᵤₜ of the CBUF 135 is a constant level corresponding to the second reference voltage V_{REF2}. Accordingly, as illustrated in FIG. 12, there is no variation in the DC level of the output voltage Vₒᵤₜ. As a result, securing the stabilization time for the stabilization of the DC level may not be needed.

In an embodiment, noise mainly occurs in a power portion or an active element of the ICELL 131, the IOFS 132, and the TIA 133, and propagates to the R2R 134. Generally, in order to reduce noise in a circuit, a large current is applied to the circuit, but to this end, a large circuit area is needed. In contrast, according to an embodiment of the disclosure, the noise propagates to the R2R 134 is voltage-divided by the 1R-2R ladder circuit main body portion 343 so as to be reduced. In other words, as a sub-block is connected in order to the ICELL 131, the IOFS 132, the TIA 133, and the R2R 134, it is difficult for noise occurring at the front end of the DAC 13 to propagate to the rear end. Accordingly, the performance of signal to noise (SNR) in the DAC 13 may be generally determined by the R2R 134 and the CBUF 135. Accordingly, there is no need to apply a large current to the ICELL 131, the IOFS 132, and the TIA 133. Accordingly, the ICELL 131, the IOFS 132, and the TIA 133 may be implemented by a small area and small consumption power.

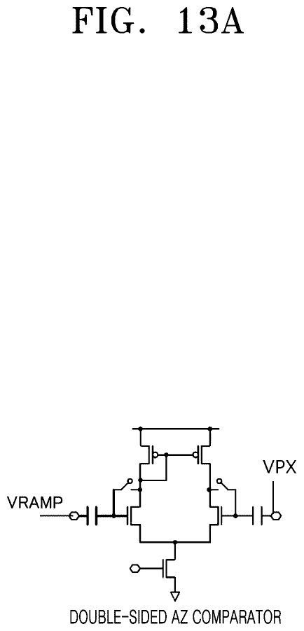

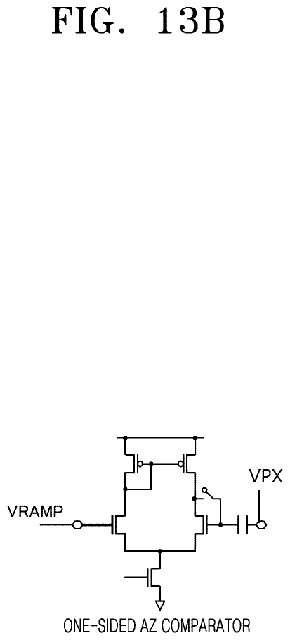

FIG. 13A is a circuit diagram showing as an example of a double-sided auto-zero (AZ) comparator. FIG. 13B is a circuit diagram showing an example of a one-sided AZ comparator.

As illustrated in FIG. 13A, the double-sided AZ comparator may include two input portions that respectively receive the ramp signal VRAMP and the pixel signal VPX, and each input portion may include an input capacitor that cuts off a DC component. The one-sided AZ comparator may include, in an input portion, an input capacitor that cuts off a DC component of the pixel signal VPX, not an input capacitor that cuts off a DC component of the ramp signal VRAMP.

In the DAC according to the comparative example, as the DC level of the output voltage varies, there is a need to use a double-sided AZ comparator (FIG. 13A) including an input capacitor in the input portion of the ramp signal VRAMP.

In contrast, according to an embodiment as described above, the DC level of the output voltage Vₒᵤₜ of the DAC 13 does not vary. Also, by changing the second reference voltage V_{REF2} input to the non-inverting input terminal of the operational amplifier 352 of the CBUF 135, the DC level of the output voltage Vₒᵤₜ may be set to a certain value. Accordingly, the input capacitor that cut off the DC component of the ramp signal VRAMP is unnecessary. Accordingly, any one of the double-sided AZ comparator illustrated in FIG. 13A and the one-sided AZ comparator illustrated in FIG. 13B may be used. In an example case in which the one-sided AZ comparator is used, as one input capacitor may be reduced, an area occupied by a circuit of the comparator 15 on the substrate may be reduced compared with a case of using the double-sided AZ comparator.

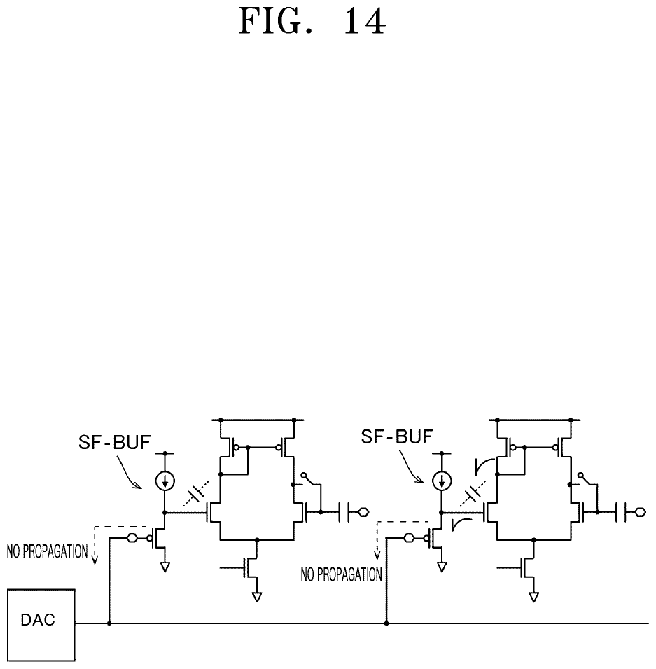

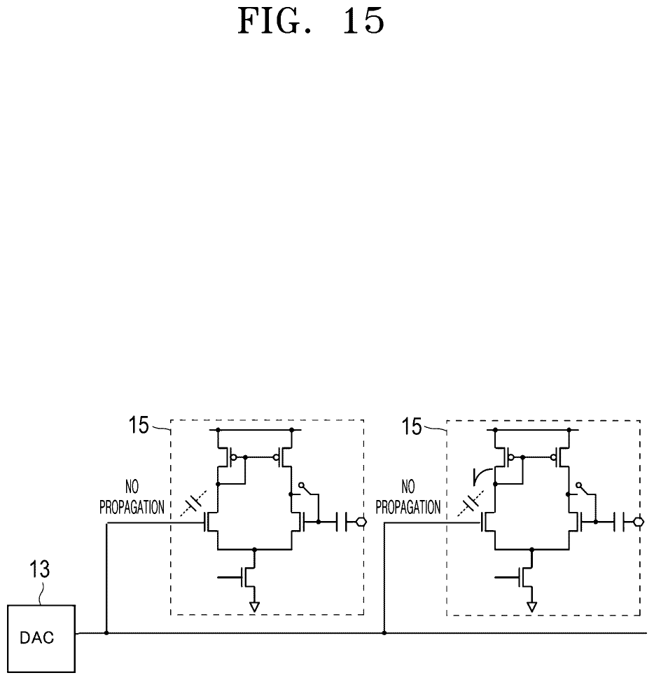

FIG. 14 is a circuit diagram showing an example of a comparator that includes a source follower-buffer. FIG. 15 is a circuit diagram showing an example of a comparator that does not include a source follower-buffer.

As illustrated in FIG. 14, a comparator that receives a ramp signal from the DAC according to the comparative example may include a source follower-buffer (hereinafter, referred to as “SF-BUF”) at the input portion to reduce interference between columns. In an example case in which the comparator includes the SF-BUF, there is an effect on the reduction of interference between columns, but there may be an increase in the area occupied by the SF-BUF on the substrate, the power consumed by the SF-BUF, and noise generated by the SF-BUF.

In contrast, in the DAC 13 according to an embodiment of the disclosure, as the output voltage Vₒᵤₜ of the CBUF 135 is buffer-driven by the buffer driving circuit, output impedance is very small so that propagation of noise is difficult. Accordingly, as illustrated in FIG. 15, the comparator 15 that receives a ramp signal from the DAC 13 according to an embodiment may not include the SF-BUF in the input portion. In an example case in which the comparator that receives a ramp signal from the DAC according to the comparative example does not include the SF-BUF, there may be an effect of the interference between columns.

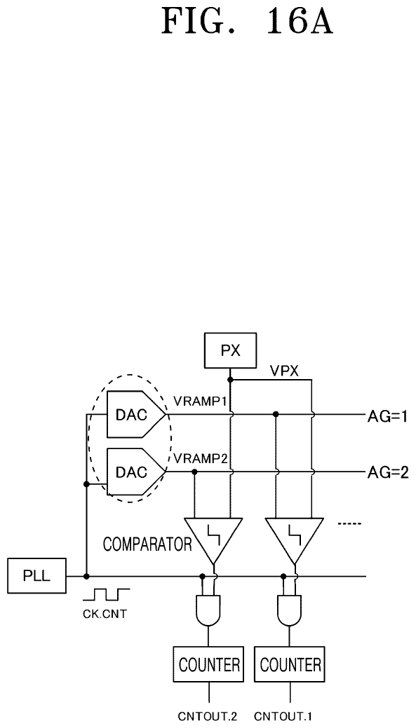

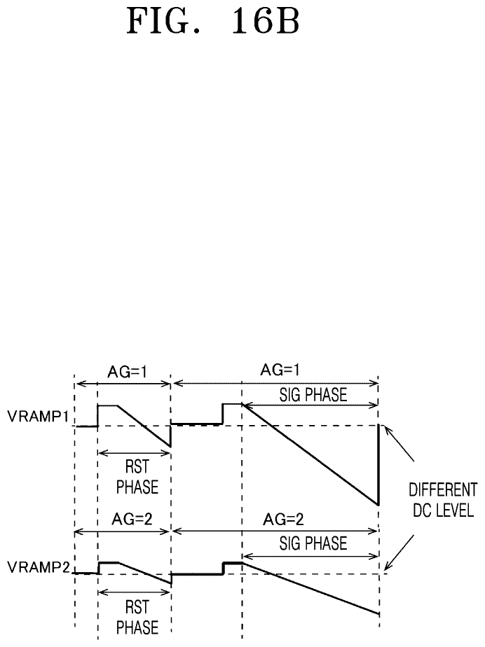

FIG. 16A is a circuit diagram showing an example of a configuration for DSG driving by using the DAC according to the comparative example. FIG. 16B is a waveform diagram showing an example of an operation by the configuration of FIG. 16A.

In the DAC according to the comparative example, when the value of the analog gain AG changes, the DC level of the output voltage also changes, and thus a solid-state imaging device including the DAC according to the comparative example does not need to have a DAC for each analog gain AG. For example, as illustrated in FIG. 16A, when the analog gain AG changes in two ways of 1 (one time) and 2 (two times), the solid-state imaging device needs to have two DACs. As illustrated in FIG. 16B, a first ramp signal VRAMP1 may be output from a DAC in which the analog gain AG is set to 1, and a second ramp signal VRAMP2 may be output from a DAC in which the analog gain AG is set to 2.

In contrast, in the DAC 13 according to an embodiment of the disclosure, the DC level of the output voltage Vₒᵤₜ is constant, and also the analog gain AG may be dynamically adjusted. Accordingly, as the solid-state imaging device 10 needs to include at least one DAC 13, compared with the solid-state imaging device according to the comparative example, the circuit scale of the solid-state imaging device 10 may be reduced and also consumption power may be reduced.

In the example illustrated in FIG. 9B, a case in which the analog gain AG changes for each phase (e.g., the analog gain AG changes from 1 to 2) is described. However, the disclosure is not limited thereto, and the inclination of a slope of the ramp signal VRAMP may be changed by changing the analog gain AG within one phase (e.g., SIG phase). In other words, the DAC 13 may have a plurality of slopes of different inclinations within one phase.

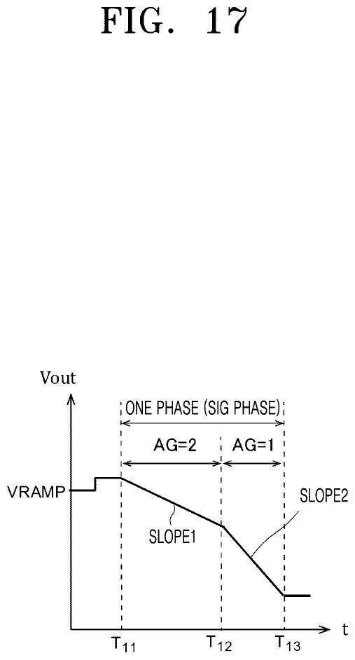

FIG. 17 is a waveform diagram showing an example of the waveform of a ramp signal having a plurality of slopes of different inclinations in one phase, according to an embodiment. In FIG. 17, the vertical axis represents the output voltage Vₒᵤₜ of the DAC 13, and the horizontal axis represents time. In the disclosure, a plurality of slopes having different inclinations within one phase are referred to as a multi-slope (MS).

According to an embodiment, the multi-slope may be easily implemented by dynamically changing the capacitor ratio C₁/C₂ of the CBUF 135 within one phase. In the example illustrated in FIG. 17, within one phase from T₁₁ to T₁₃, the analog gain AG is set to 2 in a section from T₁₁ to T₁₂, and the analog gain AG is set to 1 in a section from T₁₂ to T₁₃. Accordingly, the ramp signal VRAMP may have a slope 1 in the section from T₁₁ to T₁₂, and a slope 2 in the section from T₁₂ to T₁₃. The inclination of the slope 2 is greater than the inclination of the slope 1.

As such, by adjusting the capacitor ratio C₁/C₂ during outputting of a ramp signal, the analog gain AG may be switched from “2” (first value) to “1” (second value). According to an embodiment, the output voltage Vₒᵤₜ in the CBUF 135 has low output impedance because the output voltage Vₒᵤₜ is buffer-driven by the buffer driving circuit. Accordingly, as described above, even when the inclination of a slope changes in the middle, the delay time may be minimized.

In addition, although the waveform of a ramp signal having two slopes of different inclinations within one phase is described as an example, the disclosure is not limited to two slopes, and the analog gain AG may be set to have three or more slopes.

The DAC 13 according to an embodiment described above may have the following effects.

The DAC 13 may include the ICELL 131, the TIA 133 that converts a signal variation of the output current of the ICELL 131 into a voltage, the R2R 134 that voltage-divides the output voltage of the TIA 133 at a certain ratio, and the CBUF 135 that amplifies the output voltage of the R2R 134 through buffer driving and generates and outputs a ramp signal. Accordingly, while the DC level of the output voltage Vₒᵤₜ is latched constant, the settling time of the ramp wave may be shortened.

Also, as the area occupied by the resistor on the substrate can be reduced, the area on the substrate occupied by the DAC 13 according to an embodiment may be reduced compared with the DAC according to the comparative example.

Furthermore, due to the improvement in the function of the DAC 13, the circuit of the ADC 30 that receives the ramp signal from the DAC 13 can be simplified (circuit scale reduction), and consumption power may be reduced. As a result, as the whole solid-state imaging device 10, compared with the solid-state imaging device according to the comparative example, the circuit area and the consumption power may be reduced.

A case in which the DAC 13 of FIG. 3 outputs one output voltage Vₒᵤₜ is described above. A case in which a DAC outputs P output voltages V(n=1, 2, 3, . . . , P)ₒᵤₜ by the analog gain is described below.

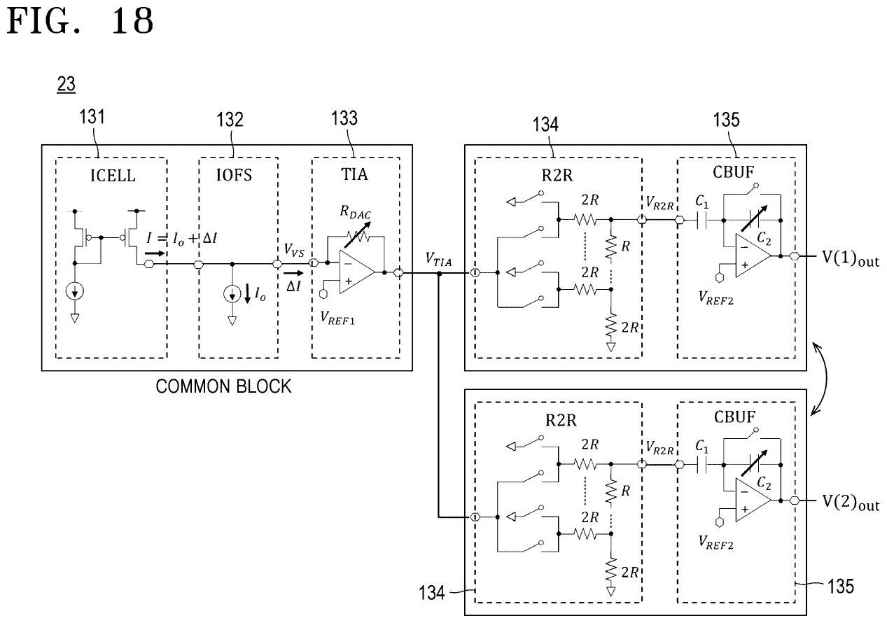

FIG. 18 schematically illustrates a DAC 23 according to an embodiment. In FIG. 18, the DAC 23 outputs two output voltages V(1)ₒᵤₜ and V(2)ₒᵤₜ. In the following description, to avoid redundant descriptions, descriptions on the same configuration as that of the DAC 13 of FIG. 3 is omitted or simplified.

As described above, the DAC 13 according to an embodiment described with reference to FIG. 3 has a constant DC level of the output voltage Vₒᵤₜ, and furthermore, the analog gain AG may be dynamically adjusted. Accordingly, even when the analog gain AG needs to be adjusted, it is sufficient for the solid-state imaging device 10 to have only one DAC 13.

In an example case in which the output voltage Vₒᵤₜ needs to be output as a plurality of output voltages independently, the ICELL 131, the IOFS 132, and the TIA 133 are included one each as a common block, and two sub-blocks of the R2R 134 and the CBU 135 may be included as a plurality of sets.

For example, as illustrated in FIG. 18, the DAC 23 according to an embodiment may include a common block including the ICELL 131, the IOFS 132, and the TIA 133. Furthermore, the DAC 23 may include two sets of two sub-blocks of the R2R 134 and the CBUF 135. The input terminal 341 of the R2R 134 in each set is connected in parallel to the output terminal 333 of the TIA 133 of the common block.

In the design of a semiconductor circuit of the solid-state imaging device 10, by duplicating a module of the two sub-blocks of the R2R 134 and the CBUF 135, the DAC 23 that outputs the two output voltages V(1) out and V(2) out may be easily implemented. Likewise, the DAC 23 that outputs P output voltages V(n=1, 2, 3, . . . , P) out may be easily implemented by a method of duplicating a module of (P−1) sets of sub-blocks, thereby facilitating the design of a DAC. According to an embodiment of the disclosure, an effect of easily extending the function of a DAC by using (reusing) the design of the DAC 13 of FIG. 3 may be obtained.

As such, according to an embodiment of the disclosure, the DAC 23, which includes a plurality of sets of the R2R 134 and the CBUF 135 in parallel, may obtain an effect of simultaneously outputting a plurality of ramp signals of another analog gain AG by parallel-processing the output of the TIA 133, in addition to the effects of the DAC 13 of FIG. 3.

A method of changing the resolution of an SS-ADC according to an embodiment is described below.

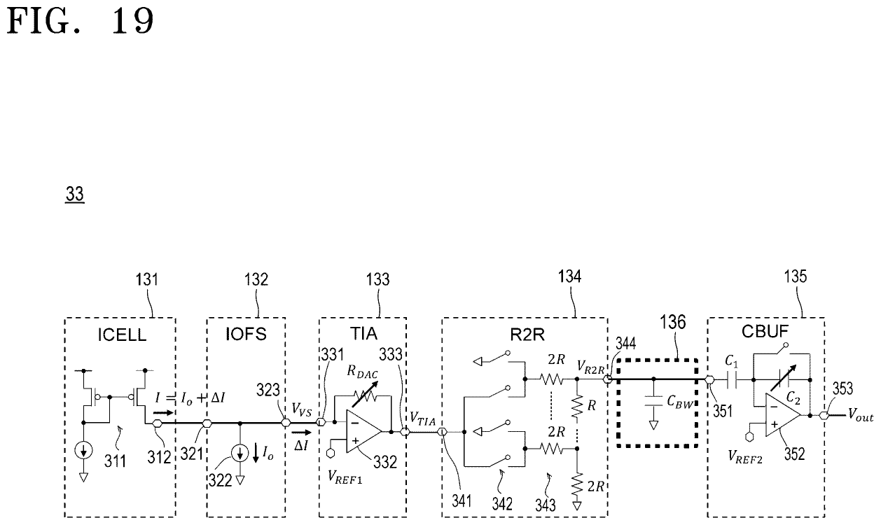

FIG. 19 schematically illustrates a DAC according to an embodiment.

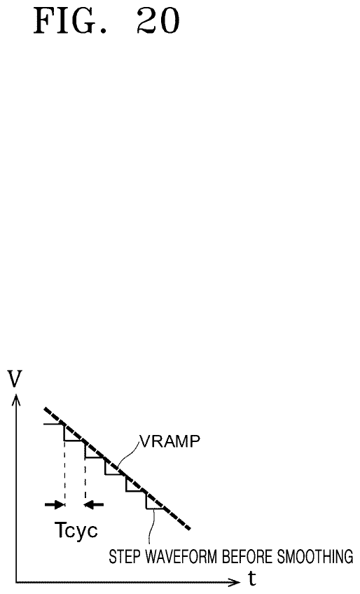

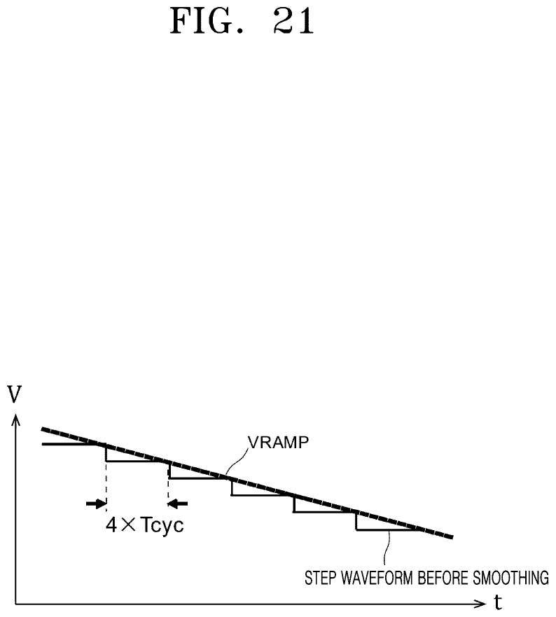

FIG. 20 is a waveform diagram showing an example of the inclination of the slope of a ramp signal before changing the resolution capability of an SS-ADC. FIG. 21 is a waveform diagram showing an example of the inclination of the slope of a ramp signal after changing the resolution capability of the SS-ADC. In addition, redundant descriptions are omitted or simplified in the following description.

As illustrated in FIG. 19, in an embodiment, a DAC 33 may include the ICELL 131, the IOFS 132, the TIA 133, the R2R 134, and the CBUF 135, and include a band limiting portion 136 between the output terminal 344 of the R2R 134 and the input terminal 351 of the CBUF 135. The band limiting portion 136 may include a band limiting capacitor CBW.

For example, a case of changing an SS-ADC having a 10-bit resolution to an SS-ADC having a 12-bit resolution is described. In this case, in which the resolution is improved by 2 bits, the PLL 14 is set to divide the clock signal CK_CNT by 4(=2²), and the period of the clock signal CK_CNT is set to four times of the period T_{eye} of the embodiment of FIG. 20.

As illustrated in FIG. 20, before changing the resolution of an SS-ADC, the output voltage V_{R2R} of the R2R 134 has a step waveform that monotonically decreases with a width of the period Teyc. As illustrated in FIG. 21, after changing the resolution of an SS-ADC, the output voltage V_{R2R} of the R2R 134 has a step waveform that monotonically decreases with a width of four times of the period T_{eye}.

In an example case in which the period of a clock signal is extended to four times of the period T_{eye}, compared with a case in which the period of a clock signal is the period T_{eye}, the step waveform of the output voltage V_{R2R} of the R2R 134 becomes coarser. In contrast, by including the band limiting capacitor C_{BW}, the output voltage V_{R2R} of the R2R 134 is smoothed by the band limiting capacitor C_{BW} and the RC load of the CBUF 135. As the frequency of a clock signal is divided by four and the band limiting capacitor C_{BW} is added to divide a band by four, an ADC having a 12-bit resolution may be implemented.

In addition, although the resolution may be improved by increasing the number of unit current source cells in the current source cell, in this case, the area of the current source cell increases by the increase in the number of unit current source cells. In an embodiment, by lowering the frequency of a clock signal, without increasing the number of unit current source cells in the current source cell, the resolution may be improved as in the case of increasing the number of unit current source cells.

As such, in an embodiment, in addition to the effect of the DAC 13 of FIG. 3, it is possible to obtain the effect of easily improving resolution while suppressing the increase in the circuit size of the DAC.

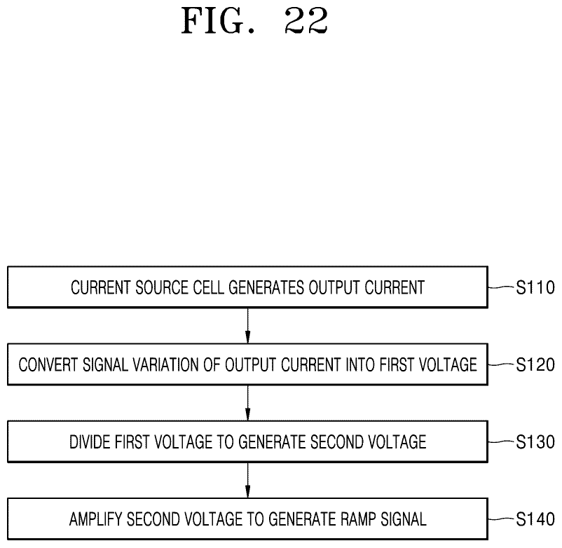

FIG. 22 is a flowchart showing an operating method of a DAC, according to an embodiment. The method according to an embodiment may be applied to the DAC 13 of FIG. 3, the DAC 23 of FIG. 18, and the DAC 33 of FIG. 19.

According to an embodiment, in operation S110, the method may include generating an output current. For example, referring to FIGS. 3 and 22, a current source cell portion (e.g., the ICELL 131 of FIG. 3) may generate the output current I according to the digital input signal DI. The output current I may have the step-like signal variation ΔI. In an example case in which the output current I has the offset current I₀, the IOFS 132 may remove the offset current I₀.

According to an embodiment, in operation S120, the method may include converting the signal variation of the output current into a first voltage. For example, a current voltage portion (e.g., the TIA 133 of FIG. 3) may convert the signal variation ΔI of the output current I into a first voltage (e.g., the output voltage V_{TIA}) (S120). The current voltage portion may be implemented by a buffer driving circuit including an operational amplifier and a feedback resistor connected between an input terminal and an output terminal of the operational amplifier. The feedback resistor may be implemented by a variable resistor, and as the resistance value of the feedback resistor changes, the analog gain AG of the DAC 13 may be adjusted.

According to an embodiment, in operation S130, the method may include dividing the first voltage to generate a second voltage. For example, as a voltage divider circuit (e.g., the R2R 134 of FIG. 3) voltage-divides the first voltage, a second voltage (e.g., the output voltage V_{R2R}) may be generated (S130). The voltage divider circuit may include an input portion including the n switches SW1 to SWn, and a 1R-2R ladder circuit, and by adjusting a resistance ratio by using n bits b₀ to bₙ₋₁ of a control signal, the gain G₁ of the voltage divider circuit (e.g., a ratio of the second voltage to the first voltage) may be adjusted, and by adjusting the gain G₁, the analog gain AG of the DAC 13 may be adjusted.

According to an embodiment, in operation S140, the method may include amplifying the second voltage to generate a ramp signal. For example, an amplifier circuit (e.g., the CBUF 135 of FIG. 3) may amplify the second voltage to generate a ramp signal (e.g., the output voltage Vₒᵤₜ) (S140). The amplifier circuit may be implemented by a buffer driving circuit including an operational amplifier, an input capacitor connected to an input terminal of the operational amplifier, and a feedback capacitor connected between the input terminal and an output terminal of the operational amplifier, and may buffer-drive a variable component of the second voltage to generate a ramp signal. The feedback capacitor may be implemented by a variable capacitor, and by changing the capacitance of the feedback capacitor (e.g., as the ratio of the input capacitor and the variable capacitance changes), the gain G₂ of the amplifier circuit may be adjusted, and by adjusting the gain G₁, the analog gain AG of the DAC 13 may be adjusted.

In an embodiment, an operation for setting (adjusting) the analog gain AG of the DAC 13 (e.g., the analog gain AG of a ramp signal) may be further included. For example, the analog gain AG may be set by setting, before S110, at least one of a resistance value of the feedback resistor of the current voltage portion, a resistance ratio of the 1R-2R ladder circuit of the voltage divider circuit, and a capacitor ratio of an input capacitor to a feedback capacitor of the amplifier circuit. For example, by adjusting, during outputting of a ramp signal, at least one of a resistance value of the feedback resistor of the current voltage portion and the capacitor ratio of the input capacitor to the feedback capacitor of the amplifier circuit, the analog gain may be dynamically adjusted.

As described above, the operating methods of the solid-state imaging device, the DAC circuit, and the DAC circuit according to some embodiments are described. However, in the disclosure, a person skilled in the art may appropriately add, modify, and omit within the scope of the technical concept.

For example, in the embodiments described above, a solid-state imaging device including a plurality of pixels with a photoelectric conversion device such as a photodiode in a light receiving portion is described as an example. However, the disclosure is not limited to this case, and may be applied to a DAC that supplies a ramp signal to an ADC that AD converts an analog signal from an optical sensor, instead of pixels. The optical sensor may include, for example, an illuminance sensor, a contrast sensor, or an infrared distance sensor.

Also, the solid-state imaging device of the disclosure may be used for various devices that sense light such as visible light, near infrared light, infrared light, ultraviolet light, and X-rays. The devices may include, although not particularly limited, for example, smartphones, mobile phones, personal computers, office equipment, vehicle equipment, medical equipment, entertainment equipment, nature observation equipment, and security equipment. For example, the solid-state imaging device of the disclosure may be used for visible light cameras of smartphones, mobile phones, or digital cameras. Also, the solid-state imaging device of the disclosure may be used for time of flight (TOF) or light detection and ranging (LiDAR) together with the light-emitting device.

While the inventive concept has been particularly shown and described with reference to embodiments thereof, it will be understood that various changes in form and details may be made therein without departing from the spirit and scope of the following claims.

What is claimed is:

1. An imaging device comprising:
an analog-digital conversion (ADC) circuit configured to convert an analog signal from a pixel into a digital signal; and
a digital-analog conversion (DAC) circuit comprising:
a current source cell;
a current-voltage conversion circuit configured to convert a signal variation of an output current of the current source cell into a first output voltage;
a voltage divider circuit configured to divide the first output voltage of the current-voltage conversion circuit at a certain ratio and output a second output voltage; and
an amplifier circuit configured to amplify the second output voltage of the voltage divider circuit by driving a buffer, generate a ramp signal based on the amplified second output voltage, and output the ramp signal to the ADC circuit.

2. The imaging device of claim 1, wherein the DAC circuit further comprises an offset circuit configured to remove a DC offset component from the output current of the current source cell.

3. The imaging device of claim 1, wherein the current-voltage conversion circuit comprises an analog gain adjustment circuit comprising a buffer driving circuit.

4. The imaging device of claim 3, wherein the analog gain adjustment circuit comprises:
an operational amplifier; and
a feedback resistor connected to an inverting input terminal of the operational amplifier.

5. The imaging device of claim 1, wherein the voltage divider circuit comprises an analog gain adjustment circuit including a 1-resistor and 2-resistor (1R-2R) ladder circuit.

6. The imaging device of claim 1, wherein the amplifier circuit comprises an analog gain adjustment circuit comprising a buffer driving circuit.

7. The imaging device of claim 6, wherein the analog gain adjustment circuit comprises an operational amplifier and a feedback capacitor connected to an inverting input terminal of the operational amplifier.

8. The imaging device of claim 1,
wherein the current-voltage conversion circuit comprises a first analog gain adjustment circuit comprising:
a first operational amplifier, and
a feedback resistor connected to a first inverting input terminal of the first operational amplifier,
wherein the voltage divider circuit comprises a second analog gain adjustment circuit comprising 1-resistor and 2-resistor (1R-2R) ladder circuit,
wherein the amplifier circuit comprises a third analog gain adjustment circuit comprising:
a second operational amplifier,
a feedback capacitor connected to a second inverting input terminal of the second operational amplifier, and
an input capacitor connected between the second inverting input terminal and an output terminal of the voltage divider circuit, and
wherein an analog gain of the ramp signal is based on at least one of a resistance value of the feedback resistor, a resistance ratio of the 1R-2R ladder circuit, and a capacitor ratio of the input capacitor to the feedback capacitor.

9. The imaging device of claim 8, wherein the analog gain is dynamically adjusted based on at least one of the first analog gain adjustment circuit and the third analog gain adjustment circuit.

10. The imaging device of claim 1, wherein the DAC circuit further comprises:
a plurality of voltage divider circuits arranged in parallel, wherein the plurality of voltage divider circuits process the first output voltage of the current-voltage conversion circuit in parallel to simultaneously output a plurality of ramp signals.

11. The imaging device of claim 1, wherein the ADC circuit comprises a comparator configured to compare the analog signal from the pixel with the ramp signal, and
wherein the comparator comprises two input portions, and one of two input portions of the comparator comprises an input capacitor.

12. The imaging device of claim 8, wherein the analog gain is switched from a first value to a second value by adjusting at least one of the first analog gain adjustment circuit and the third analog gain adjustment circuit during outputting of the ramp signal.

13. The imaging device of claim 1, wherein the DAC circuit comprises a band limiting capacitor on an output side of the voltage divider circuit between the voltage divider circuit and the amplifier circuit.

14. A digital-analog conversion (DAC) circuit comprising:
a current source cell;
a current-voltage conversion circuit configured to convert a signal variation of an output current of the current source cell into a first output voltage;
a first voltage divider circuit configured to divide the first output voltage of the current-voltage conversion circuit at a first ratio and output a second output voltage; and
a first amplifier circuit configured to amplify the second output voltage of the first voltage divider circuit, generate a first ramp signal based on the second output voltage amplified by the first amplifier circuit, and output the first ramp signal to an analog-digital conversion (ADC) circuit.

15. The DAC circuit of claim 14, further comprising an offset circuit configured to remove a DC offset component from the output current of the current source cell.

16. The DAC circuit of claim 14,
wherein the current-voltage conversion circuit comprises a first analog gain adjustment circuit comprising:
a first operational amplifier, and
a feedback resistor connected to a first inverting input terminal of the first operational amplifier,
wherein the first voltage divider circuit comprises a second analog gain adjustment circuit comprising 1-resistor and 2-resistor (1R-2R) ladder circuit,
wherein the first amplifier circuit comprises a third analog gain adjustment circuit comprising:
a second operational amplifier,
a feedback capacitor connected to a second inverting input terminal of the second operational amplifier, and
an input capacitor connected between the second inverting input terminal and an output terminal of the voltage divider circuit, and
wherein an analog gain of the first ramp signal is based on at least one of a resistance value of the feedback resistor, a resistance ratio of the 1R-2R ladder circuit, and a capacitor ratio of the input capacitor to the feedback capacitor.

17. The DAC circuit of claim 14, further comprising:
a second voltage divider circuit configured to divide an output voltage of the current-voltage conversion circuit at a second ratio; and
a second amplifier circuit configured to amplify the second output voltage of the second voltage divider circuit, generate a second ramp signal based on the second output voltage amplified by the second amplifier circuit, and output the second ramp signal.

18. The DAC circuit of claim 14, further comprising a band limiting capacitor between the first voltage divider circuit and the first amplifier circuit.

19. An operating method of a digital-analog conversion (DAC) circuit for supplying a ramp signal to an analog-digital conversion (ADC) circuit, the operating method comprising:
converting, by a current-voltage conversion circuit of the DAC circuit, a signal variation of an output current from a current source cell into a first voltage;
dividing, by a voltage divider circuit of the DAC circuit, the first voltage to generate a second voltage; and
amplifying, by an amplifier circuit of the DAC circuit, the second voltage through buffer driving to generate a ramp signal.

20. The operating method of claim 19, wherein the current-voltage conversion circuit includes a first operational amplifier and a feedback resistor connected to a first inverting input terminal of the first operational amplifier,
the voltage divider circuit includes 1-resistor and 2-resistor (1R-2R) ladder circuit, and
the amplifier circuit includes a second operational amplifier, an input capacitor connected to a second inverting input terminal of the second operational amplifier, and a feedback capacitor connected between the second inverting input terminal and an output terminal of the second operational amplifier, and
wherein the operating method further comprises setting an analog gain of the ramp signal by setting at least one of a resistance value of the feedback resistor, a resistance ratio of the 1R-2R ladder circuit, and a capacitor ratio of the input capacitor to the feedback capacitor.
